(19) United States
(12) Patent Application Publication
(10) Pub. No.: US 2003/0066555 A1
(43) Pub. Date: Apr. 10, 2003

(54) Maximum power tracking technique for solar panels

(76) Inventors: Ron Shu Yuen Hui, Kowloon (HK); Henry Shu Hung Chung, Kowloon (HK); Kwok-kuen Tse, Kowloon (HK)

Correspondence Address: MERCHANT & GOULD PC, P.O. BOX 2903, MINNEAPOLIS, MN, 55402-0903, US

(21) Appl. No.: 10/005,210

(22) Filed: Dec. 4, 2001

Related U.S. Application Data
(60) Provisional application No. 60/251,119, filed on Dec. 4, 2000.

(51) Int. Cl. H01L 25/00

(52) U.S. Cl. 136/246; 250/203.4

(57) ABSTRACT

The present invention provides an apparatus and method for tracking the maximum power point of a solar panel. A pulsewidth-modulated converter, for example a SEPIC or Cuk converter, is provided between the output of the panel and the load, and a perturbation is introduced into a switching parameter of the converter.

### FIELD OF THE INVENTION

This invention relates to method and apparatus for efficiently extracting the maximum output power from a solar panel under varying meteorological and load conditions.

### BACKGROUND OF THE INVENTION

The solar panel is the fundamental energy conversion component of photovoltaic (PV) systems which have been used in many applications, such as the aerospace industry, electric vehicles, communication equipment, and others. As solar panels are relatively expensive, it is important to improve the utilization of solar energy by solar panels and to increase the efficiency of PV systems. Physically, the power supplied by the panels depends on many extrinsic factors, such as insolation (incident solar radiation) levels, temperature, and load condition. Thus, a solar panel is typically rated at an insolation level together with a specified temperature, such as 1000W/m² at 25° C. The electrical power output of a solar panel usually increases linearly with the insolation and decreases with the cell/ambient temperature.

### PRIOR ART

In practice, there are three possible approaches for maximizing the solar power extraction in medium- and large-scale PV systems. They are sun tracking, maximum power point (MPP) tracking or both. For the small-scale systems, the use of MPP tracking only is popular for the economical reason. In the last two decades, various methods including power-matching schemes, curve-fitting techniques, perturb-and-observe methods, and incremental conductance algorithms have been proposed for tracking the MPP of solar panels.

Power-matching schemes require the selected solar panels to have suitable output characteristics or configurations that can be matched with particular loads. However, these techniques only approximate the location of the MPP because they are basically associated with specific insolation and load conditions. Curve-fitting techniques require prior examination of the solar panel characteristics, so that an explicit mathematical function describing the output characteristics can be predetermined. Proposed prior methods are based on fitting the operating characteristic of the panel to the loci of the MPP of the PV systems. Although these techniques attempt to track the MPP without computing the voltage-current product explicitly for the panel power, curve-fitting techniques cannot predict the characteristics including other complex factors, such as aging, temperature, and a possible breakdown of individual cells.

The perturb-and-observe (PAO) method is an iterative approach that perturbs the operation point of the PV system, in order to find the direction of change for maximizing the power. This is achieved by periodically perturbing the panel terminal voltage and comparing the PV output power with that of the previous perturbation cycle. Maximum power control is achieved by forcing the derivative of the power to be equal to zero under power feedback control. This has an advantage of not requiring the solar panel characteristics. However, this approach is unsuitable for applications in rapidly changing atmospheric conditions. The solar panel power is measured by multiplying its voltage and current, either with a microprocessor or with an analog multiplier. In certain prior methods, the tracking technique is based on the fact that the terminal voltage of the solar panels at MPP is approximately at 76% of the open-circuit voltage, but this means that in order to locate the MPP, the panel is disconnected from the load momentarily so that the open-circuit voltage can be sampled and kept as reference for the control loop.

The disadvantages of the PAO method can be mitigated by comparing the instantaneous panel conductance with the incremental panel conductance. This method is the most accurate one among the above prior art methods and is usually named as the incremental conductance technique (ICT). The input impedance of a switching converter is adjusted to a value that can match the optimum impedance of the connected PV panel.

This technique gives a good performance under rapidly changing conditions. However, the implementation is usually associated with a microcomputer or digital signal processor that usually increases the whole system cost.

### SUMMARY OF THE INVENTION

According to the present invention there is provided a method for tracking the maximum power point of a solar panel, comprising:

(a) providing a pulsewidth-modulated (PWM) DC/DC converter between the output of said panel and a load, and

(b) introducing a perturbation into a switching parameter of said converter.

In a first embodiment of the invention the parameter is the duty cycle of at least one switching device in the converter. In a second embodiment of the invention the parameter is the switching frequency of at least one switching device in the converter.

According to another aspect of the invention there is provided apparatus for tracking the maximum power point of a solar panel, comprising:

(a) a pulsewidth-modulated (PWM) DC/DC converter between the output of the solar panel and a load, and

(b) means for introducing a perturbation into a switching parameter of said converter.

In the first embodiment of the invention the converter operates in switching mode and said perturbation means comprises means for introducing a perturbation into the duty cycle of at least one switching device in the said converter. In a second embodiment of the invention the converter operates in switching mode and said perturbation means comprises means for introducing a perturbation into the switching frequency of at least one switching device in the said converter.

### BRIEF DESCRIPTION OF THE DRAWINGS

Some examples of the present invention will now be described by way of example and with reference to the accompanying drawings, in which:

FIG. 1 is an equivalent circuit of a solar-panel connected to a converter,

FIG. 2 is a circuit diagram of a SEPIC converter,

FIG. 3 illustrates the operating principles of a SEPIC converter,

FIG. 4 is a block diagram of a first embodiment of the invention,

FIG. 5 illustrates an experimental set-up,

FIGS. 6(a) & (b) illustrate solar panel characteristics in the first embodiment,

FIGS. 7(a) & (b) show converter waveforms in the first embodiment,

FIGS.. 8(a) & (b) show further converter waveforms in the first embodiment,

FIGS.9(a) & (b) show further converter waveforms in the first embodiment,

FIG. 10 shows further converter waveforms in the first embodiment,

FIG. 11 is a comparison of maximum solar panel output power using the first embodiment with ideal power output,

FIG. 12 is a circuit diagram of a Cuk converter,

FIG. 13 illustrates the relationship between ε₁/β and k,

FIG. 14 is a block diagram of a method and apparatus for MPP tracking according to a second embodiment of the invention,

FIG. 15 illustrates the relationship between ε₂/β and k′,

FIG. 16 illustrates an experimental set up,

FIG. 17 shows the performance of a solar panel with MPP tracking according to the second embodiment of the invention,

FIGS.18(a) and (b) show converter waveforms in the second embodiment of the invention with the converter in DICM and DCVM modes respectively,

FIGS. 19(a)-(d) show converter waveforms in the second embodiment of the invention with the converter in DICM ((a) and (c)) and DCVM ((b) and (d)) modes respectively,

FIGS. 20(a) and (b) show further converter waveforms in the second embodiment with the converter in DICM and DCVM modes respectively, and

FIGS. 21(a) and (b) show further converter waveforms in the second embodiment with the converter in DICM and DCVM modes respectively.

### DETAILED DESCRIPTION OF PREFERRED EMBODIMENTS

Before describing a first embodiment of the invention in detail, a theoretical explanation of the principles underlying the present invention is provided.

A. Derivation of the Required Dynamic Input Characteristics of a Converter at MPP

FIG. 1 shows an equivalent circuit of the solar panel connected to a converter. The solar panel is represented by a voltage source v_{g} connected in series with an output resistance r_{g} at the MPP. The input voltage and the equivalent input resistance of the converter are vᵢ and rᵢ, respectively. As the input power Pᵢ to the converter is equal to the output power Pₒ of the solar panel,

$${P}_{i} = {P}_{o} = \frac{{v}_{i}^{2}}{{r}_{i}} \qquad ( 1 )$$

The rate of change of Pᵢ with respect to vᵢ and rᵢ can be shown to be

$$\partial {P}_{i} = 2 \frac{{v}_{i}}{{r}_{i}} \partial {v}_{i} - \frac{{v}_{i}^{2}}{{r}_{i}^{2}} \partial {r}_{i} \qquad ( 2 )$$

At the MPP, the rate of change of Pᵢ equals zero. Hence,

$$\partial {P}_{i} = 0 ⇒ \frac{\partial {v}_{i}}{\partial {r}_{i}} = \frac{{V}_{i}}{2 {R}_{i}} \qquad ( 3 )$$

where Vᵢ and Rᵢ are the input voltage and the input resistance at MPP.

The above equation gives the required dynamic input characteristics of the converter at the MPP. The input voltage will have a small-signal variation of δvᵢ. the input resistance is subject to a small-signal change of δrᵢ. That is,

$$\frac{δ {v}_{i}}{δ {r}_{i}} \approx \frac{\partial {v}_{i}}{\partial {r}_{i}} = \frac{{V}_{i}}{2 {R}_{i}} \qquad ( 4 )$$

In the following sections, a SEPIC converter is illustrated. It will be understood, however, that similar techniques can be applied to other converters, such as Cuk, buck-boost, buck, and boost converters.

B. Input Resistance and Voltage Stress of a SEPIC Converter

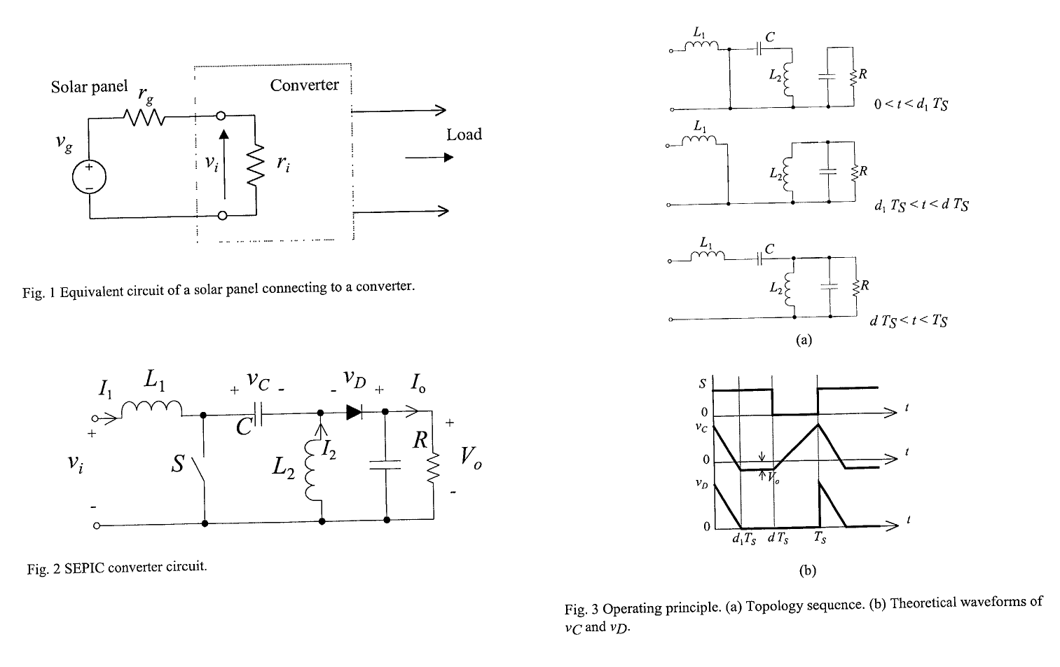

FIG. 2 shows the circuit diagram of a SEPIC converter. If the converter is operated in discontinuous capacitor voltage (DCV) mode, there are in total three circuit topologies in one switching cycle (d). The sequence of operation and the waveforms are shown in FIG. 3. If the two inductor currents (i.e., I₁ and I₂) are assumed to be constant, the capacitor voltage v_{c}(t) and diode voltage v_{D}(t) in the respective three operating intervals can be expressed as

$$\begin{matrix}{v}_{C} ( t ) = \{ \begin{matrix}\frac{{I}_{1} ( 1 - d ) {T}_{S}}{C} - {V}_{o} - \frac{{I}_{2}}{C} t & 0 < t < {d}_{1} {T}_{S} \\ - {V}_{o} & {d}_{1} {T}_{S} < t < d {T}_{S} \\ \frac{{I}_{1}}{C} ( t - d {T}_{S} ) - {V}_{o} & d {T}_{S} < t < {T}_{S}\end{matrix} & \text{(5a)} \\ {v}_{D} ( t ) = \{ \begin{matrix}{V}_{o} + {v}_{C} ( t ) & 0 < t < {d}_{1} {T}_{S} \\ 0 & {d}_{1} {T}_{S} < t < {T}_{S}\end{matrix} \\ \text{As} {v}_{C} ( {d}_{1} {T}_{S} ) = - {V}_{o} , & \text{(5b)} \\ \begin{matrix}\frac{{I}_{1} ( 1 - d ) {T}_{S}}{C} - {V}_{o} - \frac{{I}_{2}}{C} {d}_{1} {T}_{S} = - {V}_{o} \\ ⇒ {d}_{1} = \frac{{I}_{1}}{{I}_{2}} ( 1 - d )\end{matrix} & ( 6 )\end{matrix}$$

Under the steady-state condition, the average voltage across L₂ is zero. Hence, the Vₒ is equal to the average value of v_{D}. That is,

$${V}_{o} = \frac{1}{{T}_{S}} {\int }_{0}^{{D}_{1} {T}_{S}} {v}_{D} ( t ) ⅆ t = \frac{{T}_{S}}{2 C} {I}_{1} ( 1 - d ) {d}_{1} \qquad ( 7 )$$

As the average voltage across L₁ is also zero,

$${v}_{i} = \frac{1}{{T}_{S}} {\int }_{0}^{{T}_{S}} {v}_{C} ( t ) ⅆ t = \frac{{T}_{S}}{2 C} {{I}_{1} ( 1 - d )}^{2} \qquad ( 8 )$$

Hence, the input resistance rᵢ of the converter is

$${r}_{i} = \frac{{v}_{i}}{{I}_{1}} = \frac{{( 1 - d )}^{2}}{2 C {f}_{s}} \qquad ( 9 )$$

where fₛ=1/Tₛ is the switching frequency.

Moreover, the voltage stress across the main switch S, vₛₜᵣₑₛₛ, equals

$${v}_{stress} = {v}_{C} ( {T}_{S} ) + {V}_{o} = \frac{{I}_{1}}{C} ( 1 - d ) {T}_{S} = \frac{2}{1 - d} {v}_{i} \qquad ( 10 )$$

In the first embodiment of the present invention, to be described further below, equations (9) and (10) will be used to locate the MPP of a solar panel. Since, as is known, the input resistance and the voltage stress across the main switch of a Cuk converter is same as (9) and (10), respectively, both SEPIC and Cuk converters exhibit similar rᵢ and vₛₜᵣₑₛₛ and thus they can be used to locate the MPP.

C. Dynamic Input Resistance of the Converter under Perturbation

If a small-signal sinusoidal perturbation 8d is injected into d,

d=D+δd=D+\hat{d} sin ωt, (11)

where ω=2πf and D is the nominal duty cycle at the MPP, and \hat{d} and f are the amplitude and frequency of the injected perturbation, respectively. In the following derivations, the value of f is assumed to be much smaller than fₛ.

By substituting (11) into (9), the input resistance can be expressed as

$${r}_{i} = \frac{{( 1 - D )}^{2}}{2 {f}_{S} C} - \frac{( 1 - D )}{{f}_{S} C} \hat{d} sin ω t + \frac{1}{2 {f}_{S} C} {\hat{d}}^{2} {sin}^{2} ω t \qquad ( 12 )$$

Hence, rᵢ includes two main components, namely the static resistance Rᵢ at the MPP and the dynamic resistance δrᵢ around the MPP. Each one can be expressed as

$$\begin{matrix}{R}_{i} = \frac{{( 1 - D )}^{2}}{2 {f}_{S} C} & ( 13 ) \\ \text{and} δ {r}_{i} = - \frac{( 1 - D )}{{f}_{S} C} \hat{d} sin ω t + \frac{1}{2 {f}_{S} C} {\hat{d}}^{2} {sin}^{2} ω t & ( 14 )\end{matrix}$$

By substituting (14) into (4), the input voltage variation δvᵢ at the MPP can be expressed as

$$δ {v}_{i} = δ {\overline{v}}_{i} + δ {\tilde{v}}_{i} \text{and} δ {\tilde{v}}_{i} = δ {\tilde{v}}_{i , 1} + δ {\tilde{v}}_{i , 2} \\ \text{where} δ {\tilde{v}}_{i} = \frac{{V}_{i}}{4 {( 1 - D )}^{2}} {\hat{d}}^{2} , δ {\tilde{v}}_{i , 1} = - \frac{{V}_{i}}{( 1 - D )} \hat{d} sin ω t , \\ \text{and} δ {\tilde{v}}_{i , 2} = - \frac{{V}_{i}}{4 {( 1 - D )}^{2}} {\hat{d}}^{2} cos 2 ω t . \qquad ( 15 )$$

δvᵢ is maximum when

$$ω t = \frac{( 2 n + 1 )}{2} π , n = 1 , 3 , 5 , … \qquad ( 16 )$$

Its maximum value δ\overline{V}_{i,max} can be shown to be equal to

$$δ {v}_{i , max} = \frac{{V}_{i}}{( 1 - D )} \hat{d} + \frac{{V}_{i}}{2 {( 1 - D )}^{2}} {\hat{d}}^{2} \qquad ( 17 )$$

Consider the ac-component of δvᵢ, its maximum value δ\overline{V}_{i,max} can be expressed as

$$δ {\tilde{v}}_{i , max} = δ {\tilde{v}}_{i , m1} + δ {\tilde{v}}_{i , m2} \\ \text{where} δ {\tilde{v}}_{i , m1} = \frac{{V}_{i}}{( 1 - D )} \hat{d} \text{and} δ {\tilde{v}}_{i , m2} = \frac{{V}_{i}}{4 {( 1 - D )}^{2}} {\hat{d}}^{2} . \qquad ( 18 )$$

The ratio between the magnitude of δ\overline{V}_{i,1} and Sδ\overline{V}_{i,m2}, [symbol] , is

$$ℜ = \vert \frac{δ {\tilde{v}}_{i , m2}}{δ {\tilde{v}}_{i , m1}} \vert = \frac{\hat{d}}{4 ( 1 - D )} \qquad ( 19 )$$

[symbol] is an index showing the spectral quality of the input voltage variation at the frequency of the injected perturbation with respect to the amplitude of the perturbation. The smaller the value of [symbol] is, the more dominant is the component of the injected frequency in δvᵢ.

D. Voltage Stress of the Main Switch Under Perturbation

The maximum value of Vₛₜᵣₑₛₛ (i.e., V_{stress, max}) under a sinusoidal perturbation can be obtained by substituting d=D+δd and vᵢ=Vᵢ+δvᵢ into (10). Thus,

$$\begin{matrix}{v}_{stress} = \frac{2}{( 1 - D - δ d )} ( {V}_{i} + δ {v}_{i} ) \\ = \frac{2}{( 1 - D )} \frac{1}{1 - \frac{δ d}{( 1 - D )}} ( {V}_{i} + δ {v}_{i} ) \\ = \frac{2}{( 1 - D )} [ 1 + \frac{1}{( 1 - D )} δ d + \frac{1}{{( 1 - D )}^{2}} δ {d}^{2} + … ] ( {V}_{i} + δ {v}_{i} ) \\ = \frac{2}{( 1 - D )} {V}_{i} + \frac{2 δ d}{{( 1 - D )}^{2}} ( \frac{1}{1 - \frac{δ d}{1 - D}} ) \\ ( {V}_{i} + δ {v}_{i} ) + \frac{2}{1 - D} δ {v}_{i} \\ = {V}_{stress} + δ {v}_{stress}\end{matrix} \\ \text{where} {V}_{stress} = \frac{2 {V}_{i}}{( 1 - D )} \\ \text{and} δ {v}_{stress} = \frac{2 δ d}{{( 1 - D )}^{2}} ( \frac{1}{1 - \frac{δ d}{1 - D}} ) ( {V}_{i} + δ {v}_{i} ) + \frac{2}{( 1 - D )} δ {v}_{i} . \qquad ( 20 )$$

The maximum value of vₛₜᵣₑₛₛ, v_{stress,max}, can be approximated by substituting δd=\hat{d} and δvᵢ=δv_{i,max} in (17) into (20). It can be shown that

$${v}_{stress , max} = \frac{2 {V}_{i}}{( 1 - D )} [ 1 + ϵ ( D ) ] \\ \text{where} ϵ ( D ) = \frac{2 \hat{d} ( 1 - D + \frac{\hat{d}}{4} )}{( 1 - D ) ( 1 - D - \hat{d} )} . \qquad ( 21 )$$

Comparing (18) and (21), it can be shown that

$$δ {\tilde{v}}_{i , max} = β {v}_{stress , max} , β = \frac{\hat{d}}{2} [ \frac{( 1 - D - \hat{d} ) ( 1 - D + \frac{\hat{d}}{4} )}{{( 1 - D )}^{2} + \hat{d} ( 1 - D + \frac{\hat{d}}{2} )} ] \qquad ( 22 )$$

at the MPP. If \hat{d}<<1−D, β≅\hat{d}/2. Thus, δ\overline{v}_{i,max} and V_{stress,max} form a relatively constant ratio of 13 at the MPP.

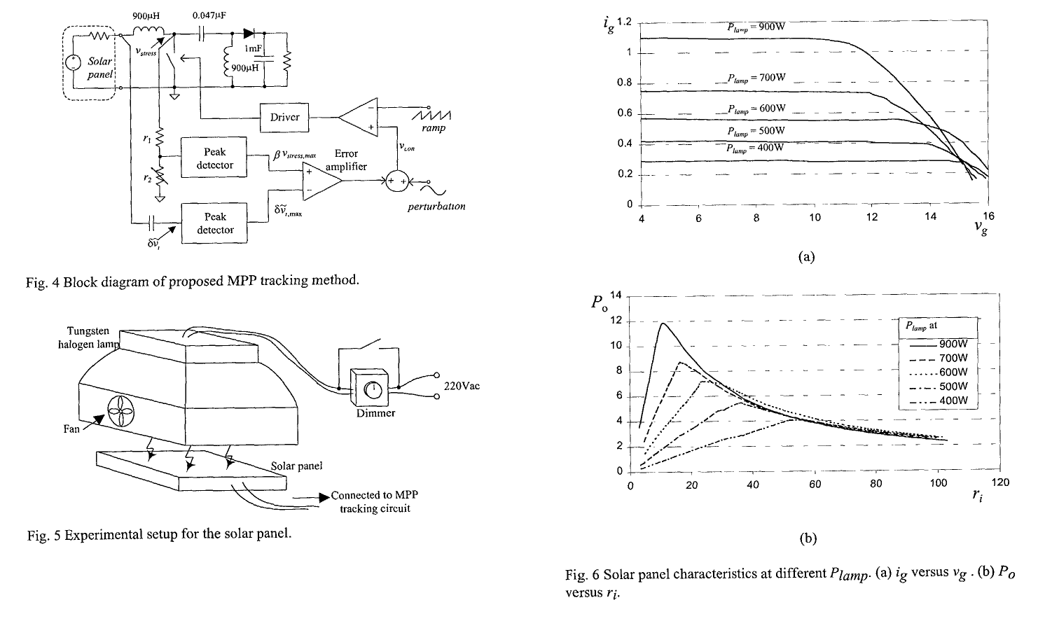

FIG. 4 is a block diagram of apparatus for locating the MPP according to a first embodiment of the invention. First, the error amplifier compares the maximum input ripple voltage (i.e., δ\overline{v}_{i,max}) and the attenuated switch voltage stress (i.e., β′_{stress,max}) and generates an error signal. Theoretically, β′ should be equal to 1 in (22). However, as β is dependent on D, a constant value is used to represent it for the sake of simplicity in the implementation. Its value is equal to r₂/(r₁+r₂) so that

$${β}^{′} = \frac{{r}_{2}}{{r}_{1} + {r}_{2}} = \frac{1}{{D}_{max} - {D}_{min}} {\int }_{{D}_{min}}^{{D}_{max}} β ( D ) ⅆ D \qquad ( 23 )$$

where Dₘᵢₙ and Dₘₐₓ are the minimum and maximum duty cycle of the main switch, respectively.

Dₘₐₓ is determined by the minimum input resistance Rᵢ,min of the converter, which is also the minimum equivalent output resistance of the solar panel. By using (9),

$${D}_{max} = 1 - \sqrt{2 {R}_{i , min} C {f}_{S}} \qquad ( 24 )$$

For the converter operating in DCV mode, it must be ensured that d₁≦d. The output current Iₒ can be expressed as

$${I}_{o} = \frac{{V}_{o}}{R} = ( 1 - d ) {I}_{1} + ( 1 - {d}_{1} ) {I}_{2} ⇒ {I}_{2} = \frac{1}{1 - {d}_{1}} [ \frac{{V}_{o}}{R} - ( 1 - d ) {I}_{1} ] \qquad ( 25 )$$

d₁ is determined by substituting (6) and (7) into (25) and thus

$${D}_{min} = \sqrt{2 R C {f}_{S}} \qquad ( 26 )$$

Next, a small-signal sinusoidal perturbation is superimposed on the error signal and then the combined signal v_{con} is compared to a ramp function to generate a PWM gate signal to the main switch.

The tracking action can be illustrated by considering the values of δ\overline{v}_{i,max} and v_{stess,max} when d does not equal D. Based on FIG. 1 and using (9), it can be shown that

$$\begin{matrix}\begin{matrix}{v}_{i} = \frac{{r}_{i}}{{r}_{i} + {r}_{g}} {v}_{g} \\ ⇒ δ {v}_{i} = - \frac{2 {r}_{i} {r}_{g}}{{( {r}_{i} + {r}_{g} )}^{2}} \frac{{v}_{g}}{( 1 - d )} δ d\end{matrix} \\ \text{Thus,} & ( 27 ) \\ δ {\tilde{v}}_{i , max} = \frac{2 α}{{( 1 + α )}^{2}} \frac{{v}_{g}}{( 1 - d )} \hat{d} & ( 28 )\end{matrix}$$

where α=rᵢ/r_{g}=[(1−d)/(1−D)]².

By substituting (27) and (28) into (20), V_{stress,max} is equal to

$${v}_{stress , max} = \frac{2 α [ ( 1 + α ) ( 1 - d ) + 2 \hat{d} ]}{( 1 - d ) ( 1 - d - \hat{d} ) {( 1 + α )}^{2}} {v}_{g} \qquad ( 29 )$$

Referring to (22), if \hat{d}<<1−d, β≅\hat{d}/2. It can be shown that

$$Φ = \frac{{β}^{′} {v}_{stress , max}}{δ {v}_{i , max}} ≅ \frac{1}{2} [ \frac{( 1 + α ) ( 1 - d ) + 2 \hat{d}}{1 - d - \hat{d}} ] ≅ \frac{1}{2} ( 1 + α ) = \frac{1}{2} [ 1 + {( \frac{1 - d}{1 - D} )}^{2} ] \qquad ( 30 )$$

When rᵢ equals r_{g} (i.e., α=1), Φ becomes unity. This is the condition when the converter is at the MPP. If d is smaller than D, rᵢ will be larger than r_{g} (i.e., α>1), Φ becomes larger than unity. The error amplifier will then generate a signal so as to increase the duty cycle. Conversely, if d is larger than D, rᵢ will be smaller than r_{g} (i.e., α <1). Φ becomes less than unity. The error amplifier will then generate a signal so as to decrease the duty cycle. The above regulatory actions cause the feedback network to adjust the duty cycle, in order to make Φ=1 or rᵢ=r_{g}.

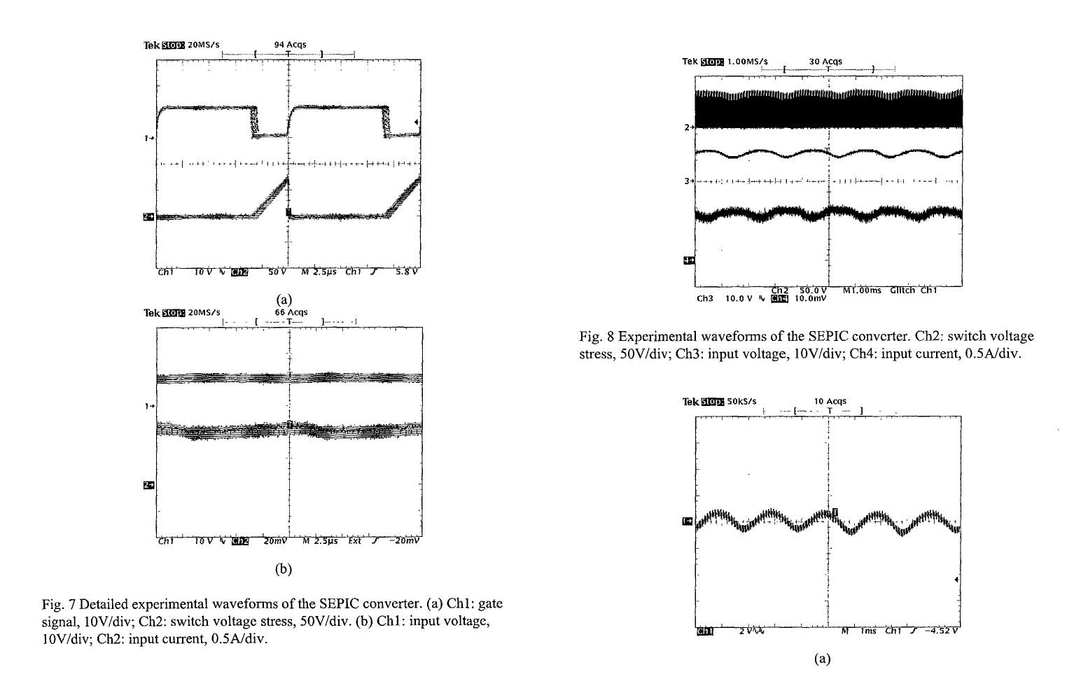

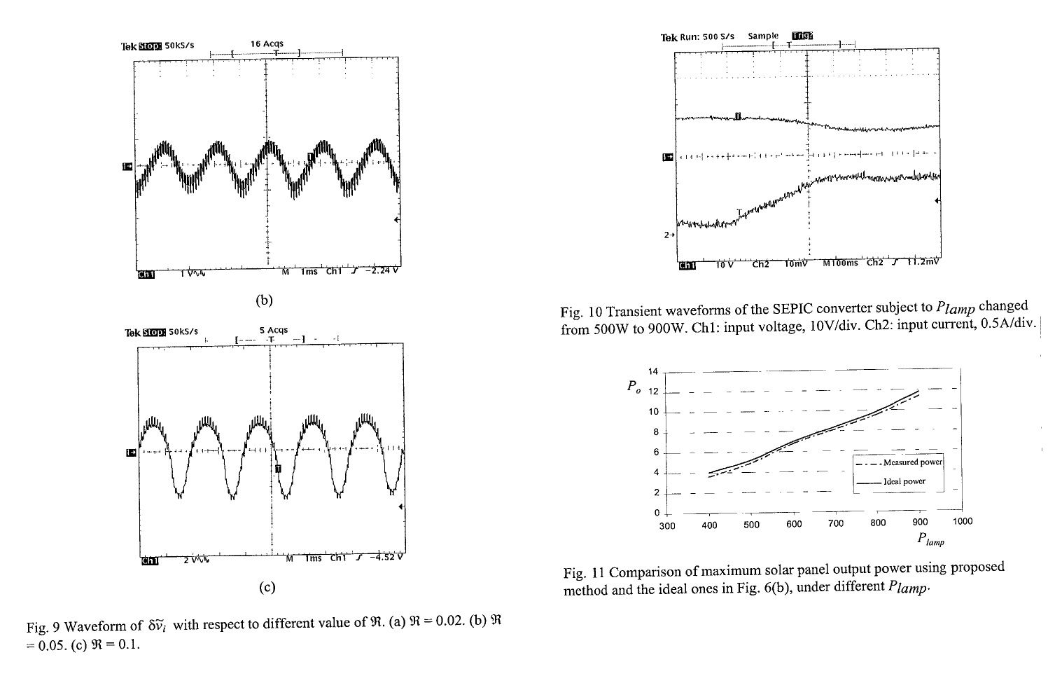

The embodiment of FIG. 4 has been experimentally checked using the set-up shown in FIG. 5 and using a solar panel Siemens SM-10 with a rated output power of 10W. The component values of the SEPIC converter are as shown in FIG. 4. The output resistance R equals 10Ω. The switching frequency is set at 80 kHz and the injected sinusoidal perturbation frequency is 500 Hz. The radiation level illuminated on the solar panel is adjusted by controlling the power of a 900W halogen lamp using a light dimmer. The bypass switch is used to give the maximum brightness from the lamp for studying the transient response. The surface temperature of the panel is maintained at about 40° C. The measured v_{g}-i_{g} characteristics and the output power versus the terminal resistance of the solar panel at different power Pₗₐₘₚ to the lamp are shown in FIG. 6(a) and FIG. 6(b), respectively. Under a given Pₗₐₘₚ, it can be seen that the panel output power will be at its maximum under a specific value of the terminal resistance. When Pₗₐₘₚ equals 900W (i.e., full power), the required terminal resistance is 14Ω, in order to extract maximum power from the solar panel. Thus, by applying (24) and (26), Dₘᵢₙ and Dₘₐₓ equal 0.274 and 0.675, respectively. Based on (9), the variation of the input resistance is between 14 Ω and 70 Ω, which are well within the required tracking range of the input resistance shown in FIG. 6(b).

Detailed experimental waveforms of the gate signal, the switch voltage stress, the converter input terminal voltage, and the input inductor current in one switching cycle at the maximum lamp power are shown in FIG. 7. Macroscopic views of the switch voltage stress, input voltage, and input current are shown in FIG. 8. It can be seen that a low-frequency variation of 500 Hz is superimposed on all waveforms. They are all in close agreement with the theoretical ones. In addition, the input current is continuous. Thus, the MPP tracking method and apparatus of this embodiment of the present invention is better than the one using classical buck-type converter which takes pulsating input current. Moreover, it is unnecessary to interrupt the system, in order to test the open-circuit terminal voltage of the solar panel.

FIG. 9 shows the ac-component of the converter input terminal voltage with 91 equal to 0.02, 0.05, and 0.1, respectively. As [symbol] increases, the ac-component will be distorted because the second-order harmonics become dominant in (15).

In order to observe the feedback action of the proposed approach under a large-signal variation in the radiation level, Pₗₐₘₚ is changed from 500W to 900W. The transient waveform of the feedback signal is shown in FIG. 10. The settling time is about 0.4 seconds. Based on the results in FIG. 6(b), a comparison of the maximum attainable output power and the measured output power with the proposed control scheme under different Pₗₐₘₚ is shown in FIG. 11. It can be seen that the proposed control technique can track the output power of the panel with an error of less than 0.2W. A major reason for the discrepancy is due to the variation of D with respect to the duty cycle shown in (23), which will directly affect the tracking accuracy.

The methodology of this first embodiment of the invention is based on connecting a pulsewidth-modulated (PWM) DC/DC converter between a solar panel and a load or battery bus. In this embodiment a SEPIC converter operates in discontinuous capacitor voltage mode whilst its input current is continuous. By modulating a small-signal sinusoidal perturbation into the duty cycle of the main switch and comparing the maximum variation in the input voltage and the voltage stress of the main switch, the maximum power point (MPP) of the panel can be located. The nominal duty cycle of the main switch in the converter is adjusted to a value, so that the input resistance of the converter is equal to the equivalent output resistance of the solar panel at the MPP. This approach ensures maximum power transfer under all conditions without using microprocessors for calculation.

In the first embodiment of the invention described above, a small perturbation is introduced into the duty cycle of at least one switching device in the converter. In a second embodiment of the invention, to be described in more detail below, a small perturbation may be introduced into the switching frequency of a PWM DC/DC converter. Before describing the second embodiment in more detail, further theoretical explanation is offered below. SEPIC and Cuk converters operating in discontinuous inductor current mode (DICM) and discontinuous capacitor voltage mode (DCVM) are illustrated.

A. Discontinuous Inductor Current Mode (DICM)

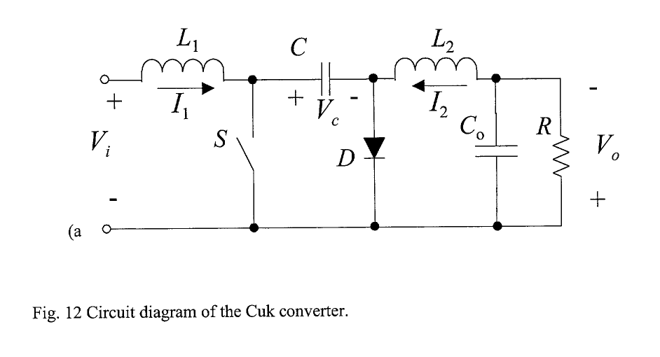

The input characteristics of SEPIC (FIG. 2) and Cuk converters (FIG. 12) are similar. The input resistance rᵢ equals

$${r}_{i} = \frac{2 {L}_{e} {f}_{S}}{{d}^{2}} , \qquad ( 31 )$$

where Lₑ=L₁//L₂, fₛ is the switching frequency, and d is the duty cycle of the switch S in FIGS. 2 and 12.

By differentiating (31) with respect to fₛ, it can be seen that a small change of fₛ will introduce a small variation in rᵢ. That is,

$$δ {r}_{i} = \frac{2 {L}_{e}}{{d}^{2}} δ {f}_{S} . \qquad ( 32 )$$

Hence, if fₛ is modulated with a small-signal sinusoidal variation

f_{S}=\overline{f}_{S}+δ\overline{f}_{S}=\overline{f}_{S}+\overline{f}_{S} sin(2 πfₘt), (33)

where \overline{f}_{S} is the nominal switching frequency, fₘ is the modulating frequency and is much lower than \overline{f}_{S}, and \overline{f}_{S} is the maximum frequency deviation.

Thus, with the above switching frequency perturbation, rᵢ will include an average resistance Rᵢ and a small variation δrᵢ. That is,

rᵢ=Rᵢ+δrᵢ, (34)

$$\begin{matrix}\text{where} {R}_{i} = \frac{2 {L}_{e}}{{d}^{2}} {\overline{f}}_{S} , & ( 35 ) \\ \text{and} δ {r}_{i} = \frac{2 {L}_{e}}{{d}^{2}} {\hat{f}}_{S} sin ( 2 π {f}_{m } t ) . & ( 36 )\end{matrix}$$

Let D_{MP} be the required duty cycle of S at MPP. r_{g} can be expressed as

$${r}_{g} = \frac{2 {L}_{e} {\overline{f}}_{S}}{{D}_{MP}^{2}} . \qquad ( 37 )$$

By using (35) and (37),

$${V}_{i} = \frac{{R}_{i}}{{R}_{i} + {r}_{g}} {v}_{g} = \frac{{D}_{MP}^{2}}{{D}_{MP}^{2} + {d}^{2}} {v}_{g} \qquad ( 38 )$$

and the variation of vi with respect to rᵢ becomes

$$δ {v}_{i} \approx \frac{ⅆ}{ⅆ {r}_{i}} ( \frac{{r}_{i}}{{r}_{i} + {r}_{g}} {v}_{g} ) δ {r}_{i} = \frac{{r}_{g} {v}_{g}}{{( {R}_{i} + {r}_{g} )}^{2}} δ {r}_{i} \qquad ( 39 )$$

By substituting (32), (35), and (37) into (39), the small-signal variation on vᵢ is

$$δ {v}_{i} = \frac{{( {D}_{MP} d )}^{2} {v}_{g}}{{( {D}_{MP}^{2} + {d}^{2} )}^{2} {\overline{f}}_{S}} δ {f}_{S} . \qquad ( 40 )$$

The peak value of δvᵢ (i.e., \hat{v}ᵢ) becomes

$${\hat{v}}_{i} = \frac{{( {D}_{MP} d )}^{2} {v}_{g}}{{( {D}_{MP}^{2} + {d}^{2} )}^{2} {\overline{f}}_{S}} {\hat{f}}_{S} . \qquad ( 41 )$$

As v_{g} and r_{g} vary with insolation and temperature, d should be automatically adjusted to D_{MP} in the controller. The following equation holds at the MPP and is obtained by substituting (32) and (35) into (30),

$$\frac{{\hat{f}}_{S}}{2 \overline{{f}_{S}}} {V}_{i} = {\hat{v}}_{i} \qquad ( 42 )$$

Based on (38) and (41), the difference, ε₁, between the normalized characteristics of

$$\frac{{\hat{f}}_{S} {V}_{i}}{2 {\overline{f}}_{S} {v}_{g}} and \frac{{\hat{v}}_{i}}{{v}_{g}}$$

can be shown to be equal to

$${ϵ}_{1} ( k ) = \frac{{\hat{f}}_{S} {V}_{i}}{2 {\overline{f}}_{S} {v}_{g}} - \frac{{\hat{v}}_{i}}{{v}_{g}} = β 1 - \frac{{k}^{2}}{{( 1 + {k}^{2} )}^{2}} \qquad ( 43 )$$

where k=d/D_{MP} and β=\hat{f}_{S}/(2 \overline{f}_{S}).

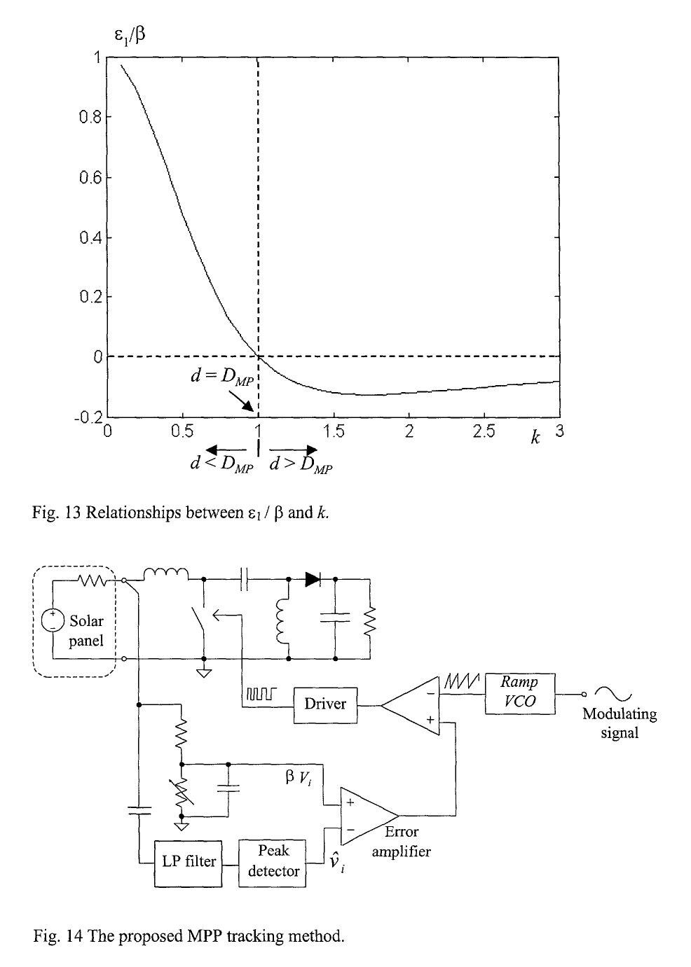

FIG. 13 shows the relationships between ε₁/β and k. It can be concluded that,

Ifd<D_{MP}(i.e., k<1), ε₁(k)>0 (44a)

If d=D_{MP}(i.e., k=1), ε₁(1)=0 (44b)

If d>D_{MP}(i.e., k>1), ε₁(k)<0 (44c)

Based on (44), the proposed MPP tracking method of a second embodiment of the invention is shown as a block diagram in FIG. 14. fₛ is modulated with a small-signal sinusoidal variation. Vi and \overline{v}ᵢ are sensed. Vi is then scaled down by the factor of β and is compared with \hat{v}ᵢ. \hat{v}ᵢ is obtained by using a peak detector to extract the value of the ac component in vᵢ. The switching frequency component in vᵢ is removed by using a low-pass (LP) filter. The error amplifier controls the PWM modulator to locate d at D_{MP}. If \hat{v}ᵢ is smaller than (\hat{f}ₛ/2\hat{f}ₛ) Vᵢ, ε₁>0. The output of the error amplifier, and hence d, will be increased. Conversely, d will be decreased until d=D_{MP}. It can be seen from the above than the proposed technique will keep track the output characteristics of solar panels without approximating the voltage-current relationships.

B. Discontinuous Capacitor Voltage Mode (DCVM)

In this mode, rᵢ equals

$${r}_{i} = \frac{{( 1 - d )}^{2}}{2 {f}_{S} C} \qquad ( 45 )$$

Thus, δrᵢ with respect to the frequency variation δfₛ is

$$δ {r}_{i} = - \frac{{( 1 - d )}^{2}}{2 {\overline{f}}_{S}^{2} C} δ {f}_{S} . \qquad ( 46 )$$

Similar to deriving (38) and (40), it can be shown that

$$\begin{matrix}{V}_{i} = \frac{{( 1 - d )}^{2}}{{( 1 - d )}^{2} + {( 1 - {D}_{MP} )}^{2}} {v}_{g} and & ( 47 ) \\ {\hat{v}}_{i} = \frac{{( 1 - d )}^{2} {( 1 - {D}_{MP} )}^{2} {v}_{g}}{{[ {( 1 - d )}^{2} + {( 1 - {D}_{MP} )}^{2} ]}^{2} {\overline{f}}_{S}} {\hat{f}}_{S} & ( 48 )\end{matrix}$$

By substituting d=D_{MP} into (37) and (48), (42) is still valid. Again, the difference, ε₂, between the nominal characteristics of

$$\frac{{\hat{f}}_{S} {V}_{i}}{2 {\overline{f}}_{S} {v}_{g}} and \frac{{\hat{v}}_{i}}{{v}_{g}}$$

can be shown to be

$${ϵ}_{2} ( {k}^{′} ) = \frac{{\hat{f}}_{S} {V}_{i}}{2 {\overline{f}}_{S} {v}_{g}} - \frac{{\hat{v}}_{i}}{{v}_{g}} = \frac{β {k}^{′2} ( {k}^{ ′2} - 1 )}{{( {k}^{′2} + 1 )}^{2}} \qquad ( 49 )$$

where k′=(1−d)/(1−D_{MP}).

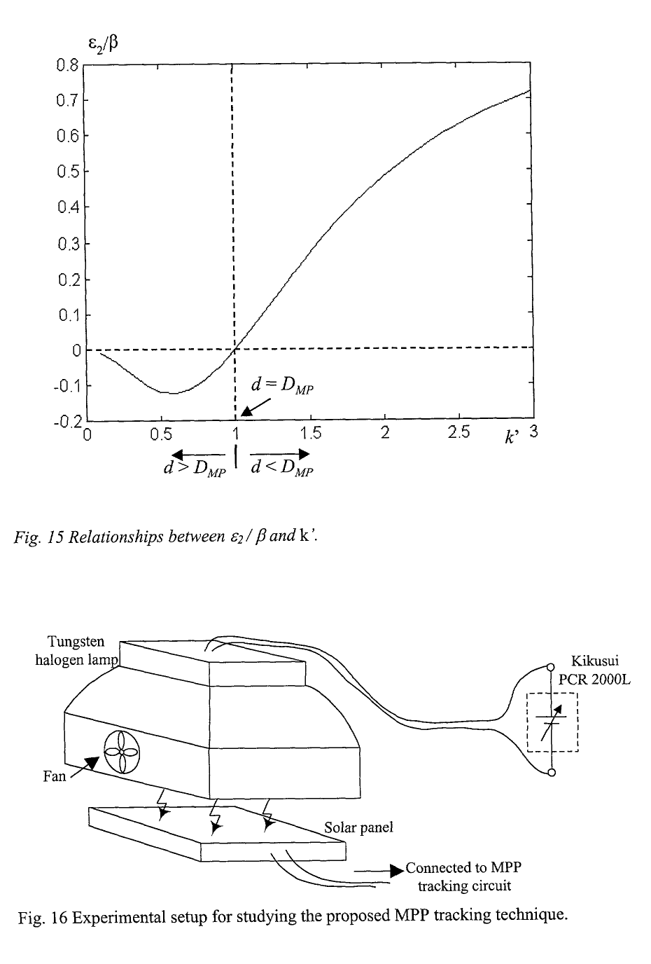

FIG. 15 shows the relationships between ε₂/β and k′. Similar behaviors as in (44) are obtained

If d<D_{MP} (k′>1), ε₂(k′)>0 (50a)

If d=D_{MP} (k′=1), ε₂ (1)=0 (50b)

If d>D_{MP} (k′<1), ε₂(k′)<0 (50c)

Hence, the control method used when the converter is operated in DICM can also be applied to a converter operated in DCVM.

C. Comparison of DICM and DCVM

Although a converter operating in DICM and DCVM can perform the MPP tracking in accordance with this embodiment of the invention, selection of a suitable operating mode is based on several extrinsic and intrinsic characteristics. Table I shows a comparison of the converter behaviors in DICM and DCVM.

TABLE I
Comparisons of the converter behaviors in DICM and DCVM

| | DICM | DCVM |
|---|---|---|
| M | $\frac{d}{{d}_{1}}$ | $\frac{{d}_{1}}{1 - d}$ |
| rᵢ | $\frac{2 {L}_{e} {f}_{S}}{{d}^{2}}$ | $\frac{{( 1 - d )}^{2}}{2 {f}_{S} C}$ |
| ΔI₁ | $\frac{2 {L}_{2}}{d ( {L}_{1} + {L}_{2} )} {I}_{1}$ | $\begin{matrix}Negligible as \\ {L}_{1} >> \frac{1}{{( 2 π {f}_{S} )}^{2} C}\end{matrix}$ |
| V_{s, max} and V_{D,,max} | (1 + M)Vᵢ | $\frac{2 M}{{d}_{1}} {V}_{i}$ |
| I_{s,max} and I_{D,max} | $\frac{2}{{Md}_{1}} {I}_{1}$ | $( 1 + \frac{1}{M} ) {I}_{1}$ |
| d₁ | $\sqrt{2 {L}_{e} {f}_{S} / R}$ | $\sqrt{2 {Rf}_{S} C}$ |
| Condition of d | <1 − d₁ | >d₁ |
| Application | High voltage, | Low voltage, |
| | low current | high current |
| Recommended arrangement | Series connection | Parallel connection |
| for solar panels | | |

For the extrinsic characteristics, apart from the difference in the voltage conversion ratio M, the input current ripple ΔI₁ in the DCVM is smaller than that in the DJCM. Thus, variation of the panel-converter operating point in the DCVM is smaller. This can effectively operate the panel at the near MPP. Nevertheless, input current perturbation is designed to be less than 10% in the implementation.

In order to ensure that the converter is operating in the DICM,

$$d < 1 - \sqrt{\frac{2 {L}_{e} {f}_{s}}{R}} = \frac{{V}_{o}}{{V}_{o} + {V}_{i}} \qquad ( 51 )$$

Thus, (51) gives the maximum duty cycle of S for a given load resistance.

In order to ensure that the converter is operating in DCVM,

$$d > \sqrt{2 R {f}_{s} C} = \frac{{V}_{o}}{{V}_{o} + {V}_{i}} \qquad ( 52 )$$

(52) gives the minimum duty cycle of S for a given load resistance.

For the intrinsic characteristics, the voltage stress V_{s,max} of S in the DCVM is higher than that in the DICM under the same panel terminal voltage and voltage conversion ratio. Conversely, the current stress I_{S,max} in the DICM is higher than that in the DCVM with the same panel output current. Thus, for the same panel power, DICM is more suitable for panel in series connection whilst DCVM is for parallel connection.

This second embodiment of the invention may be verified by means of the experiment setup shown in FIG. 16. A solar panel Siemens SM-10 with a rated output power of 10W is used. Two SEPICs, which are operating in DICM and DCVM, respectively, have been prototyped. The component values of the two converters are tabulated in Table II.

Table II Component values of the two converters

| | DICM | | DCVM | |
|---|---|---|---|---|
| L₁ | 2.2 | mH | 2.2 | mH |
| L₂ | 25 | μH | 450 | μH |
| C | 100 | μF | 47 | nF |
| C₀ | 1 | mF | 1 | mF |
| R | 10 | Ω | 10 | Ω |
| \overline{ƒ}ₛ | 50 | kHz | 50 | kHz |
| \hat{ƒ}ₛ | 10 | kHz | 10 | kHz |
| ƒₘ | 1 | kHz | 1 | kHz |

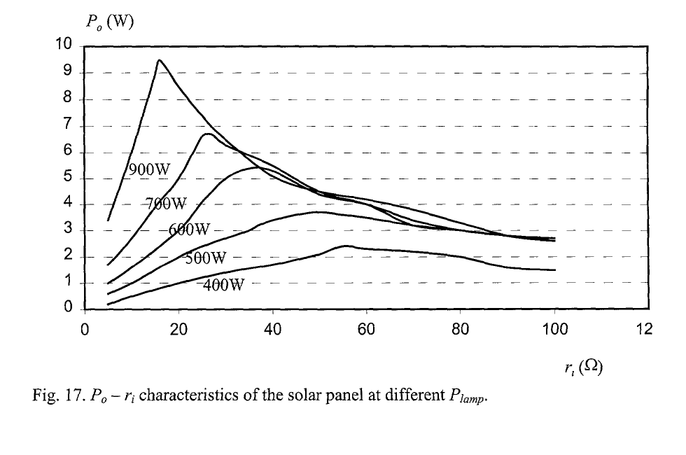

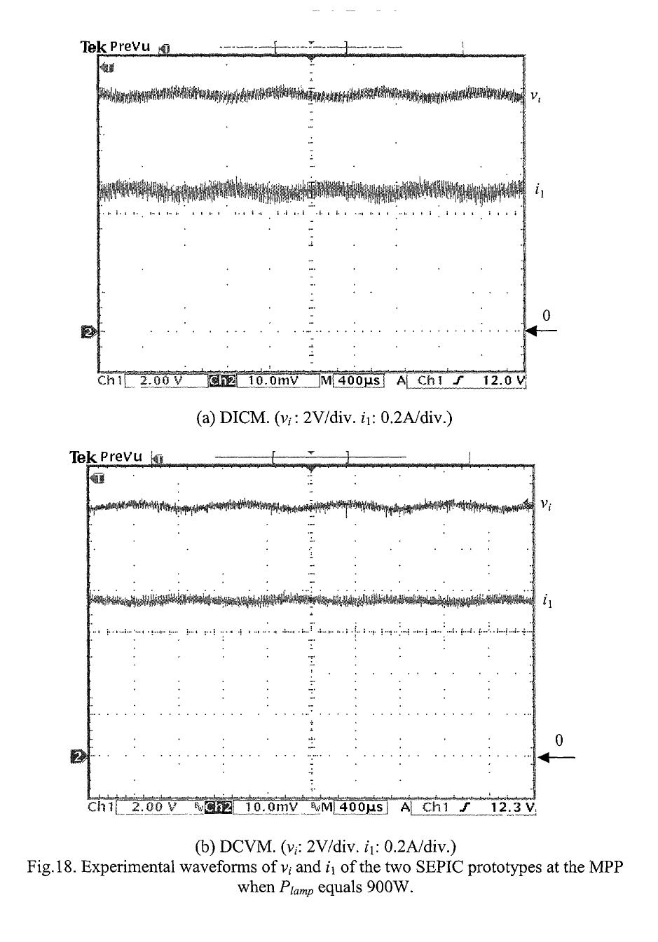

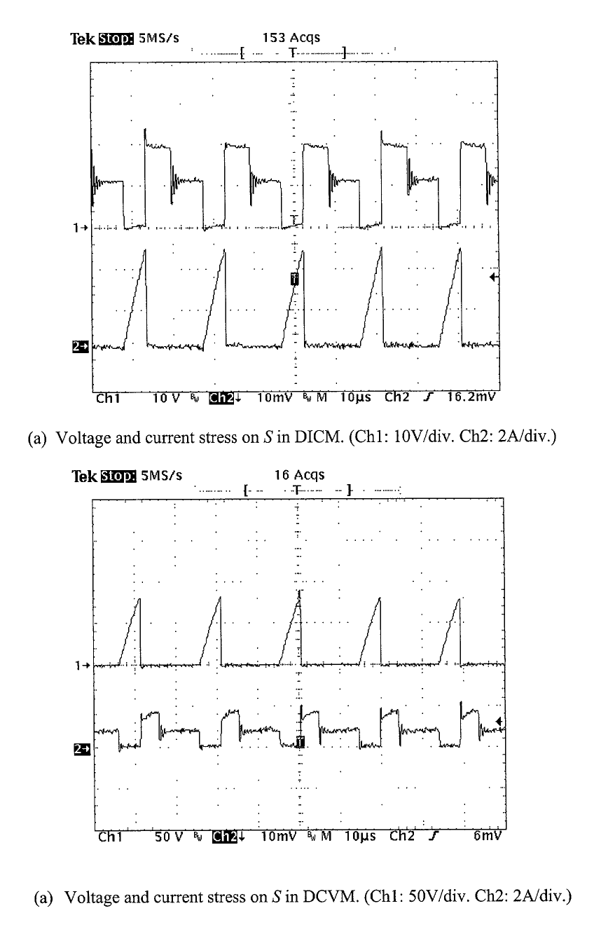

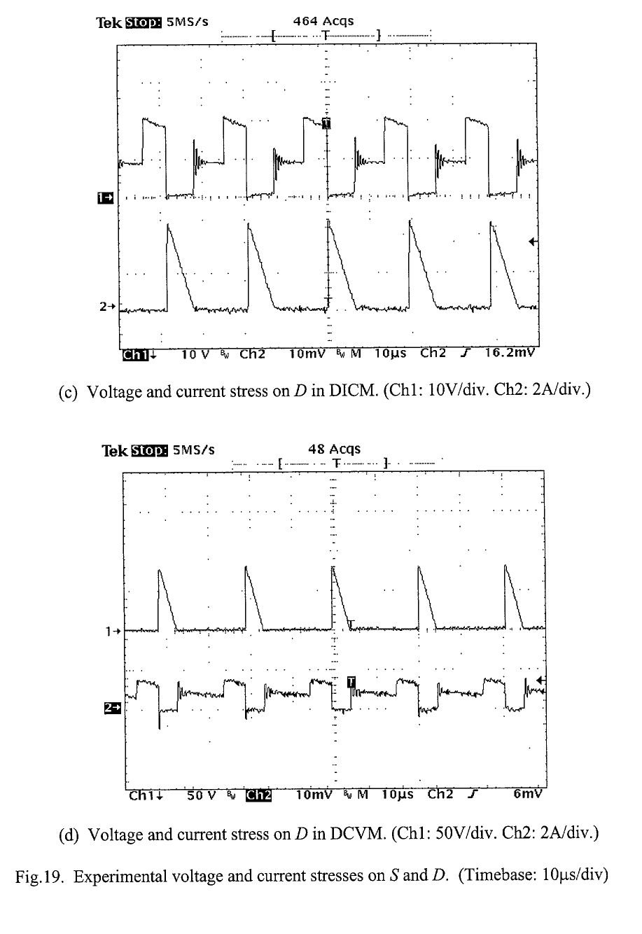

The switching frequency is 50 kHz. The modulating frequency fₘ is 1 kHz. The maximum frequency deviation \hat{f}ₛ is 10 kHz. Based on Table I and (31), the maximum value of d is 0.5 for the converter in DICM. The minimum panel output resistance that can be matched by the converter is 9.8 Ω. For the converter in DCVM, based on Table I and (35), the minimum value of d is 0.217. The maximum panel output resistance that can be matched is 130.5 Ω. The surface temperature of the panel is kept at about 40° C. throughout the test. The radiation illuminated is adjusted by controlling the power of a 900W tungsten halogen lamp using a programmable dc supply source—Kikusui PCR 2000L. FIG. 17 shows the Pₒ-rᵢ characteristics of the solar panel at different Pₗₐₘₚ. It can be seen that the output resistance of the panel at MPP varies from 18 Ω to 58 Ω when Pₗₐₘₚ is changed from 900W to 400W. The operating range is within the tracking capacity (i.e., the input resistance) of the two converters. FIG. 18 shows the experimental waveforms of vᵢ and i₁ of the two prototypes at the MPP when Pₗₐₘₚ equals 900W. It can be seen that vi has a small sinusoidal perturbation of 1 kHz. FIG. 19 shows the experimental voltage and current stresses on S and D in the two converters. As expected, the current stresses on S and D in the DICM are about three times higher than that in the DCVM, whilst the voltage stresses on S and D in the DCVM are four times higher than that in the DICM. These confirm the theoretical prediction.

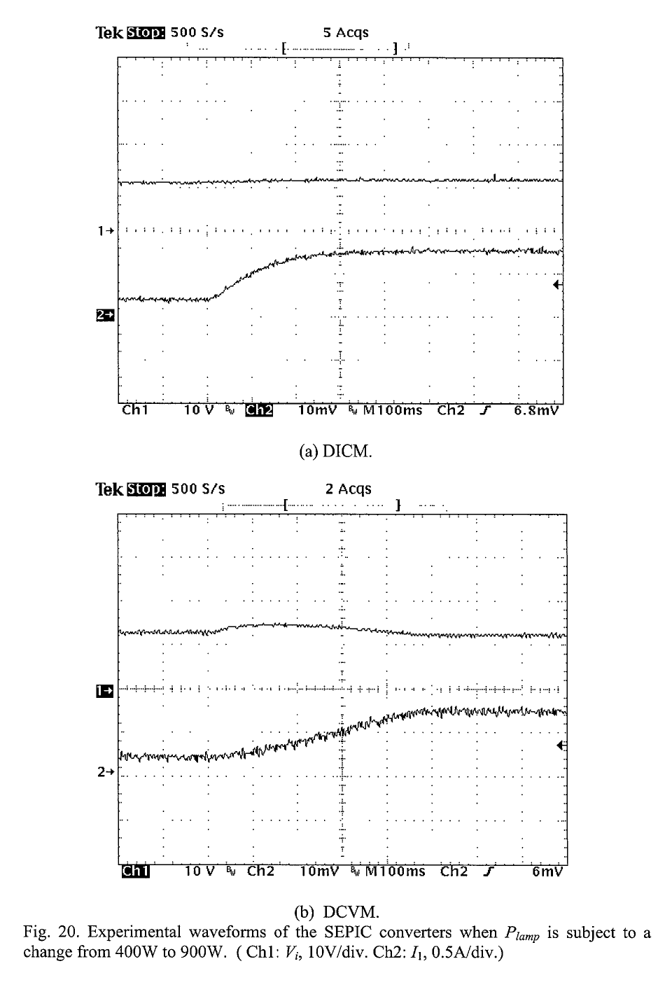

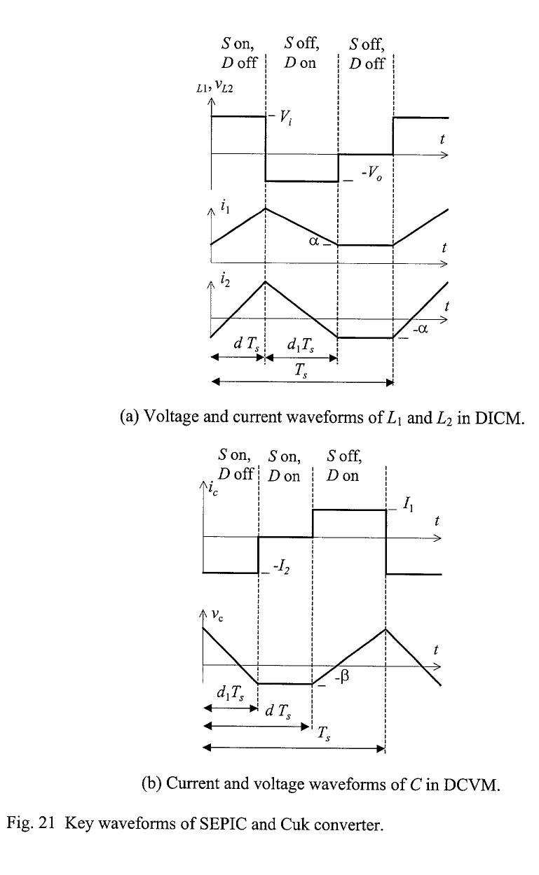

An insolation change is simulated by suddenly changing Pₗₐₘₚ from 400W to 900W. The transient waveforms of vᵢ and iᵢ of the two converters are given in FIG. 20. It was found that both converters can perform the MPP tracking function and the panel output power is increased from 2.5W to 9.5W in 0.3 sec in both cases. The tracked power is in close agreement with the measurements in FIG. 17.

It will thus be seen that at least in preferred forms of the invention novel techniques are provided for tracking the MPP of a solar panel in varying conditions. Both embodiments use either a PWM dc/dc converter, for example a SEPIC or Cuk converter. In a first embodiment of the invention a small perturbation is introduced into the duty cycle of the converter operating in discontinuous capacitor voltage mode. In the second embodiment of the invention a PWM dc/dc converter operating in discontinuous inductor-current or capacitor-voltage mode is used to match with the output resistance of the panel. In this second embodiment of the invention a small sinusoidal variation is injected into the switching frequency and comparing the maximum variation and the average value at the input voltage, the MPP can be located. Both embodiments are simple and elegant without requiring any digital computation and approximation of the panel characteristics.

1. A method for tracking the maximum power point of a solar panel, comprising:
(a) providing a pulsewidth modulated (PWM) DC/DC converter between the output of said panel and a load, and
(b) introducing a perturbation into a switching parameter of said converter.

2. A method as claimed in claim 1 wherein said parameter is the duty cycle of at least one switching device in the converter.

3. A method as claimed in claim 1 wherein said parameter is the switching frequency of at least one switching device in the converter.

4. Apparatus for tracking the maximum power point of a solar panel, comprising:
(a) a PWM DC/DC converter between the output of the solar panel and a load, and
(b) means for introducing a perturbation into a switching parameter of said converter.

5. Apparatus as claimed in claim 4 wherein said converter operates in switching mode and said perturbation means comprises means for introducing a perturbation into the duty cycle of at least one switching device of said converter.

6. Apparatus as claimed in claim 4 wherein said converter operates in switching mode and said perturbation means comprises means for introducing a perturbation into the switching frequency of at least one switching device of said converter.

7. Apparatus as claimed in claim 4 wherein said converter is a SEPIC or Cuk converter.
